(19) United States
(12) Patent Application Publication
(10) Pub. No.: US 2025/0142761 A1
(43) Pub. Date: May 1, 2025

(54) HYBRID SELF-FIXTURING FRAME

(71) Applicant: VERTIV CORPORATION, Westerville, OH (US)

(72) Inventors: Casey Anders, Prospect, OH (US); Carl Caldwell, Cardington, OH (US)

(21) Appl. No.: 18/818,028

(22) Filed: Aug. 28, 2024

Related U.S. Application Data
(60) Provisional application No. 63/546,404, filed on Oct. 30, 2023.

(51) Int. Cl. H05K 7/18; H05K 5/02

(52) U.S. Cl. CPC H05K 7/18; H05K 5/0234

(57) ABSTRACT

A self-fixturing frame assembly includes a base sub-assembly, one or more side assemblies, and a top sub-assembly. The base sub-assembly may include a base frame member configured to be coupled to an additional base frame member via two or more fasteners. Upon coupling the base frame member to the additional base frame member, the base frame member may be welded to the additional base frame member. Each side sub-assembly may include a side frame member configured to be coupled to an additional side frame member via the two or more fasteners. Upon coupling the side frame member to the additional side frame member, the side frame member may be welded to the additional side frame member. The one or more side sub-assemblies may then be coupled to the base sub-assembly upon welding. The top sub-assembly may include top frame members couplable to the one or more side sub-assemblies.

### CROSS-REFERENCE TO RELATED APPLICATIONS

The present application claims the benefit under 35 U.S.C. § 119 (e) of U.S. Provisional Application No. 63/546,404, filed Oct. 30, 2023, which is incorporated by reference in the entirety.

### TECHNICAL FIELD

The present disclosure generally relates to the field of information technology (IT) infrastructure, and more particularly to a hybrid self-fixturing frame for IT infrastructure.

### BACKGROUND

IT infrastructure, such as critical systems infrastructure (e.g., critical power infrastructure, or the like), is often housed in an enclosure or cabinet. Existing enclosures (or cabinets) include either fully welded frames or fully riveted frames. Fully welded frames require the individual components to be fixtured together to hold the components in the proper location and within the tolerance specification during the welding process. This increases assembly time and complexity, as well as requiring skilled labor. Fully riveted frames are assembled by riveting components together via one or more through holes in the components. Riveted frames do not require any special fixturing, however, the fully riveted frames are not as rigid or strong as fully welded frames. As such, there is a need for a system and method that cures one or more shortfalls mentioned above.

### SUMMARY

A self-fixturing assembly is disclosed, in accordance with one or more embodiments of the present disclosure. In embodiments, the self-fixturing frame assembly includes a base sub-assembly, the base sub-assembly including a plurality of base frame members, at least one base frame member of the plurality of base frame members coupled to an additional at least one base frame member of the plurality of base frame members via two or more fasteners, upon coupling the at least one base frame member to the additional at least one base frame member, the at least one base frame member being welded to the additional at least one base frame member. In embodiments, the self-fixturing frame assembly includes one or more side sub-assemblies, each side sub-assembly of the one or more side sub-assemblies including a plurality of side frame members, at least one side frame member of the plurality of side frame members coupled to an additional at least one side frame member of the plurality of side frame members via the two or more fasteners, upon coupling the at least one side frame member to the additional at least one side frame member, the at least one side frame member being welded to the additional at least one side frame member, the one or more side sub-assemblies couplable to the base sub-assembly upon welding the at least one side frame member to the additional at least one side frame member. In embodiments, the self-fixturing frame assembly includes a top sub-assembly, the top sub-assembly including a plurality of top frame members, where the plurality of top frame members are configured to be coupled to the one or more side sub-assemblies.

A method of fabricating a self-fixturing frame assembly is disclosed, in accordance with one or more embodiments of the present disclosure. In embodiments, the method includes fabricating a base sub-assembly by coupling at least one base frame member of a plurality of base frame members coupled to an additional at least one base frame member of the plurality of base frame members via two or more fasteners, upon coupling the at least one base frame member to the additional at least one base frame member, the at least one base frame member being welded to the additional at least one base frame member. In embodiments, the method includes fabricating one or more side sub-assemblies by coupling at least one side frame member of a plurality of side frame members coupled to an additional at least one side frame member of the plurality of side frame members via the two or more fasteners, upon coupling the at least one side frame member to the additional at least one side frame member, the at least one side frame member being welded to the additional at least one side frame member. In embodiments, the method includes upon welding the at least one side frame member to the additional at least one side frame member, coupling the one or more side sub-assemblies to the base sub-assembly via the two or more fasteners. In embodiments, the method includes coupling a top sub-assembly to the one or more side sub-assemblies, the top sub-assembly including a plurality of top frame members, where the plurality of top frame members are configured to be coupled the one or more side sub-assemblies.

In embodiments, an enclosure including: a self-fixturing frame assembly including: a base sub-assembly, the base sub-assembly including a plurality of base frame members, at least one base frame member of the plurality of base frame members coupled to an additional at least one base frame member of the plurality of base frame members via two or more fasteners, upon coupling the at least one base frame member to the additional at least one base frame member, the at least one base frame member being welded to the additional at least one base frame member; one or more side sub-assemblies, each side sub-assembly of the one or more side sub-assemblies including a plurality of side frame members, at least one side frame member of the plurality of side frame members coupled to an additional at least one side frame member of the plurality of side frame members via the two or more fasteners, upon coupling the at least one side frame member to the additional at least one side frame member, the at least one side frame member being welded to the additional at least one side frame member, the one or more side sub-assemblies couplable to the base sub-assembly upon welding the at least one side frame member to the additional at least one side frame member; and a top sub-assembly, the top sub-assembly including a plurality of top frame members, wherein the plurality of top frame members are configured to be coupled to the one or more side sub-assemblies, wherein the base sub-assembly, the one or more side sub-assemblies, and the top sub-assembly at least partially define a cavity configured to hold one or more pieces of equipment; and one or more panel walls, wherein the one or more panel walls are configured to couple to at least one of the base sub-assembly, the one or more side sub-assemblies, or the top assembly.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure.

Together, the descriptions and the drawings serve to explain the principles of the disclosure.

### BRIEF DESCRIPTION OF THE DRAWINGS

The detailed description is described with reference to the accompanying figures. The use of the same reference numbers in different instances in the description and the figures may indicate similar or identical items. Various embodiments or examples (“examples”) of the disclosure are disclosed in the following detailed description and the accompanying drawings. The drawings are not necessarily to scale. In general, operations of disclosed processes may be performed in an arbitrary order, unless otherwise provided in the claims. In the drawings:

FIG. 1A illustrates a simplified schematic of a hybrid self-fixturing assembly, in accordance with one or more embodiments of the present disclosure.

FIG. 1B illustrates a simplified schematic of a base sub-assembly of the hybrid self-fixturing assembly, in accordance with one or more embodiments of the present disclosure.

FIG. 1C illustrates a simplified schematic of a side sub-assembly of the hybrid self-fixturing assembly, in accordance with one or more embodiments of the present disclosure.

FIG. 1D illustrates a simplified schematic of a top sub-assembly of the hybrid self-fixturing assembly, in accordance with one or more embodiments of the present disclosure.

FIG. 2A illustrates an exploded view of the hybrid self-fixturing assembly, in accordance with one or more embodiments of the present disclosure.

FIG. 2B illustrates an exploded view of the hybrid self-fixturing assembly, in accordance with one or more embodiments of the present disclosure.

FIG. 2C illustrates an exploded view of the hybrid self-fixturing assembly, in accordance with one or more embodiments of the present disclosure.

FIG. 3 illustrates a simplified schematic of an enclosure including the hybrid self-fixturing assembly, in accordance with one or more embodiments of the present disclosure.

FIG. 4 illustrates a flow diagram depicting a method of process for assembling the hybrid self-fixturing assembly, in accordance with one or more embodiments of the present disclosure.

### DETAILED DESCRIPTION

Reference will now be made in detail to the subject matter disclosed, which is illustrated in the accompanying drawings.

IT infrastructure, such as critical systems infrastructure (e.g., critical power infrastructure), is often housed in an enclosure or cabinet. For example, critical power infrastructure such as, but not limited to, power distribution units (PDUs), uninterruptible power supplies (UPSs), static transfer switches (STSs), and the like may be housed in an enclosure (or cabinet) to protect the respective equipment from the environment (e.g., dirt/debris, rodents, water, and the like).

Existing frames are either fully welded at all connecting points or fully riveted. Fully welded frames require the individual components to be fixtured together to hold the components in the proper location and within the tolerance specification during the welding process. This consumes additional setup time during the assembly. Further, fully welded systems require skilled labor to weld and must be welded prior to painting (or touched up after). Fully riveted frames are assembled by riveting components together via through holes in the components. Riveted frames do not require any special fixturing, however, they are not as rigid or strong as the fully welded frames.

Accordingly, the present disclosure is directed to a hybrid self-fixturing frame assembly. More particularly, the present disclosure is directed to a hybrid self-fixturing frame assembly using a hybrid of welded and riveted components. For example, the individual components of the hybrid self-fixturing frame assembly may be self-fixturing via one or more riveted points then welded before being assembled into a system level frame assembly. As previously discussed above, existing frames utilize either fully welded frames or fully riveted frames, each with their own respective advantages and disadvantages. It is contemplated herein that the hybrid self-fixturing frame assembly of the present disclosure leverages the respective advantages of the individual techniques (e.g., welding and riveting) to provide a number of advantages over the existing frames. For example, the hybrid self-fixturing frame assembly of the present disclosure provides increased strength and rigidity versus the fully riveted assembly, reduced assembly time versus the fully welded assembly, reduction in skilled labor required, and reduced paint booth dimensions.

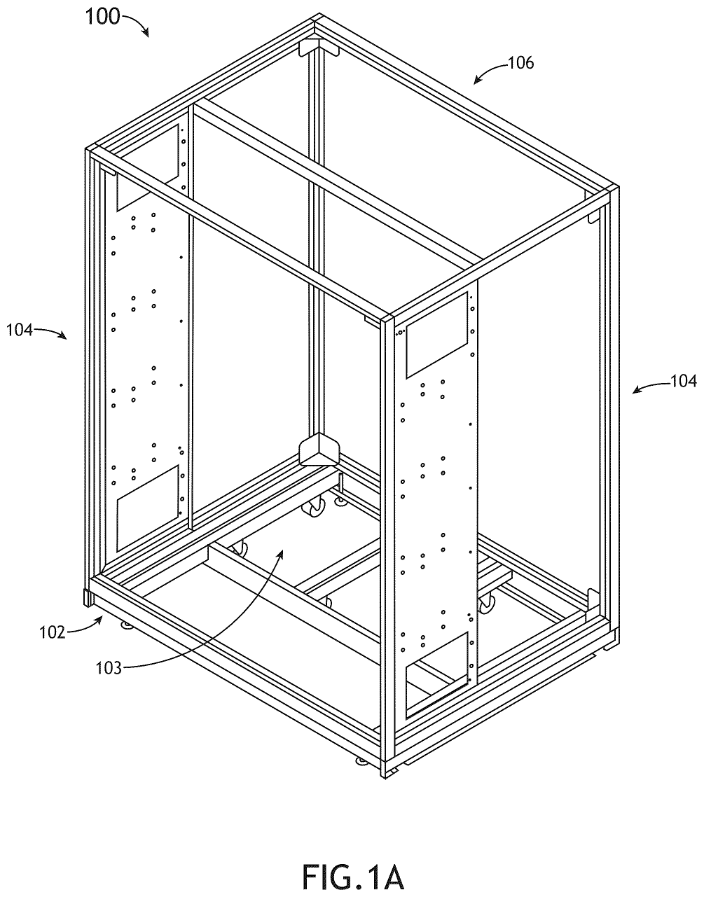

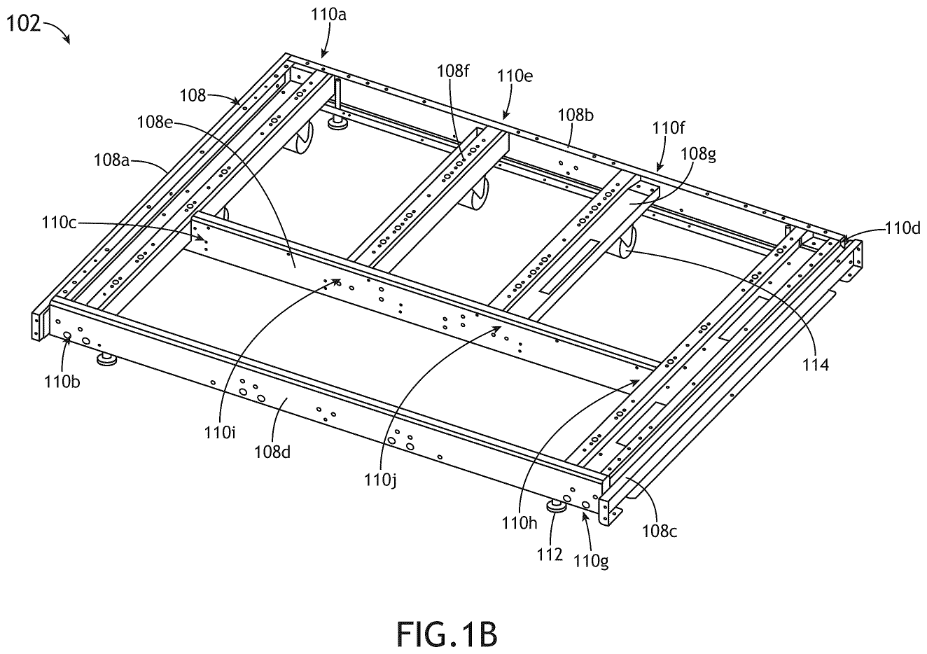

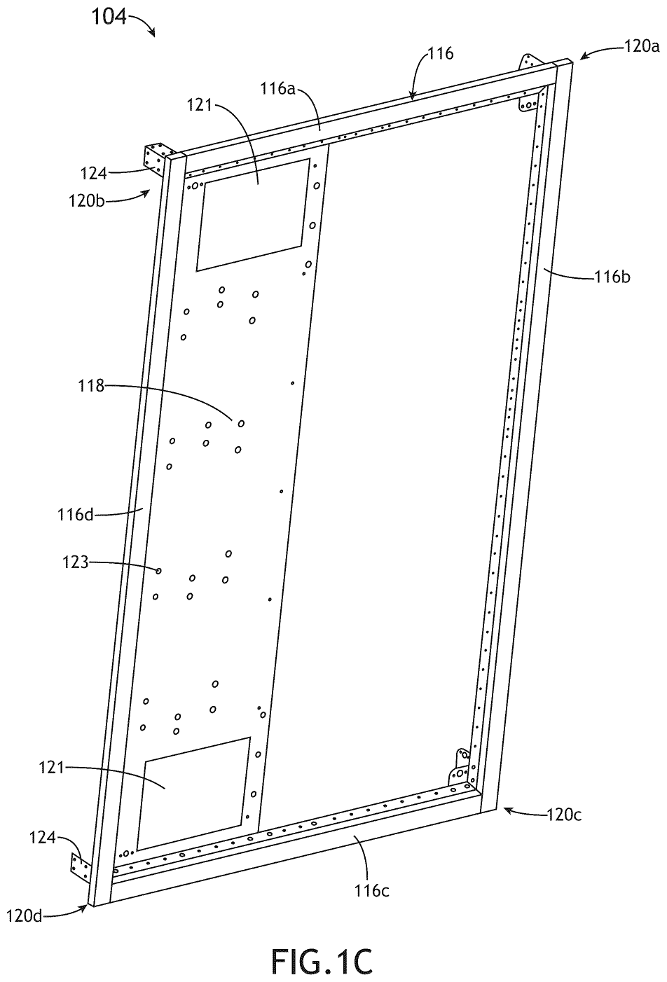

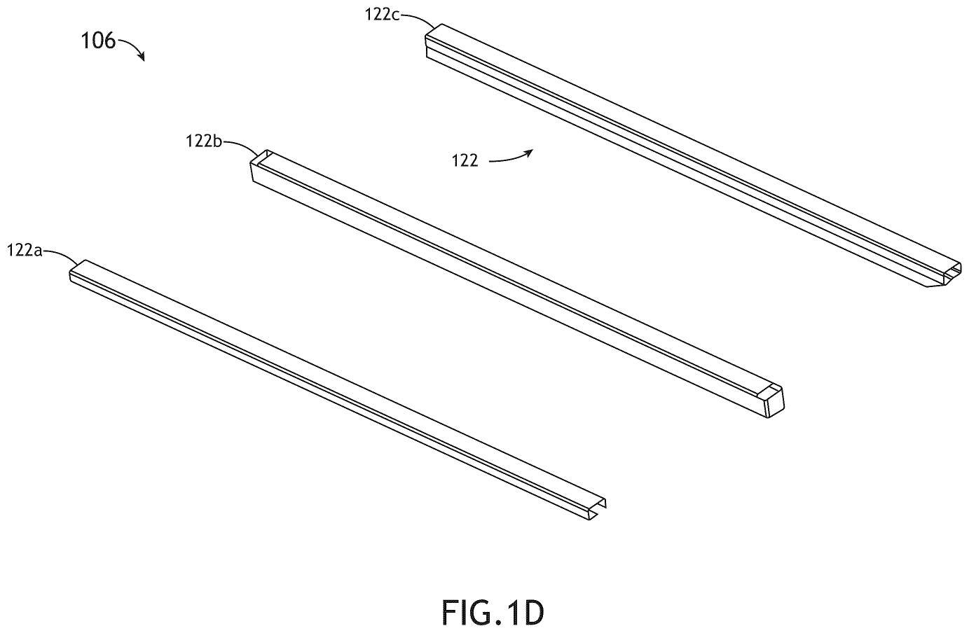

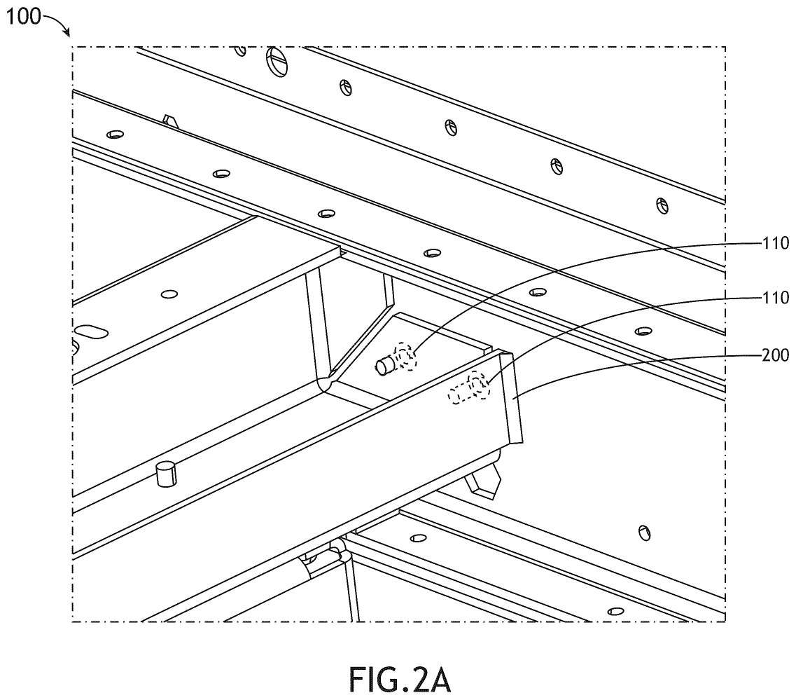

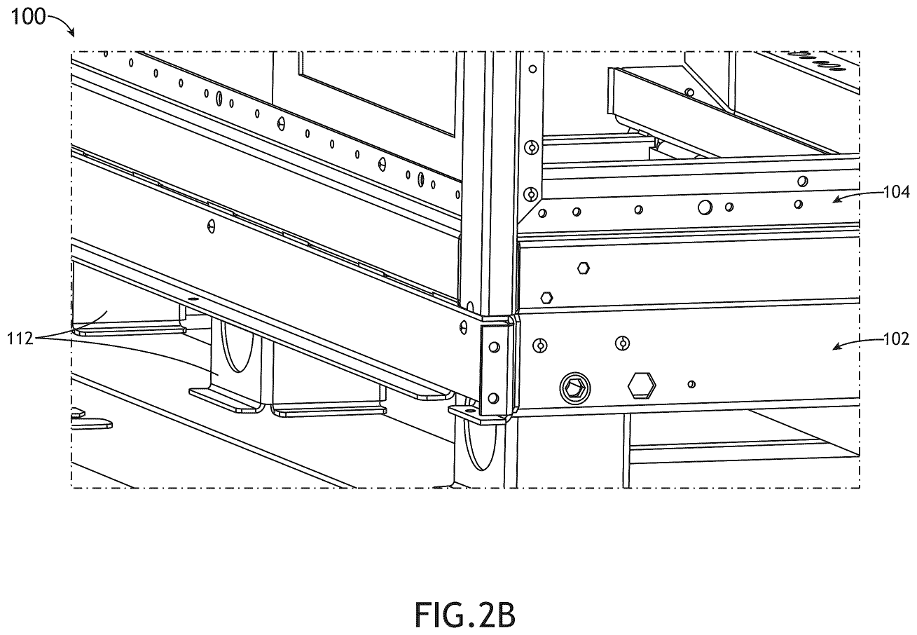

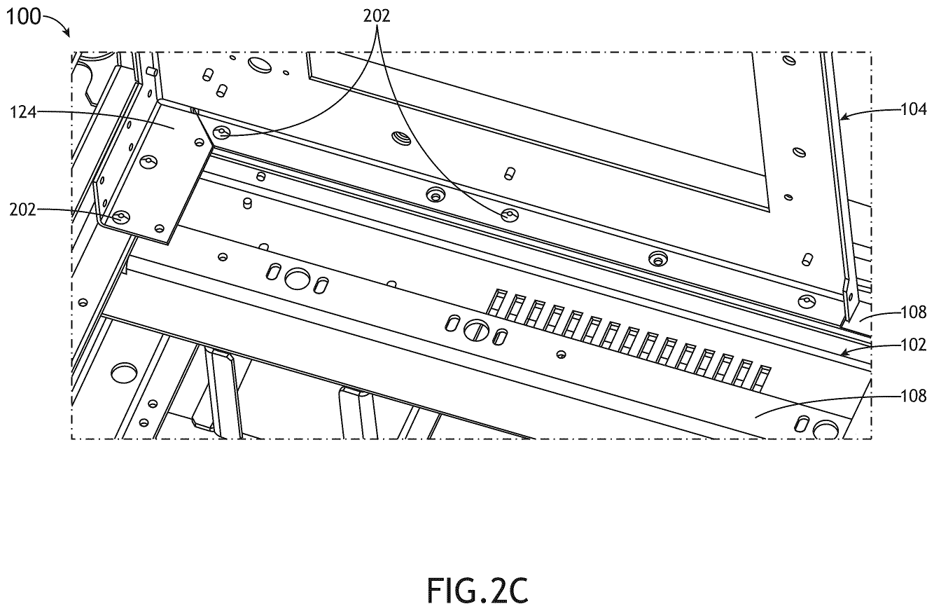

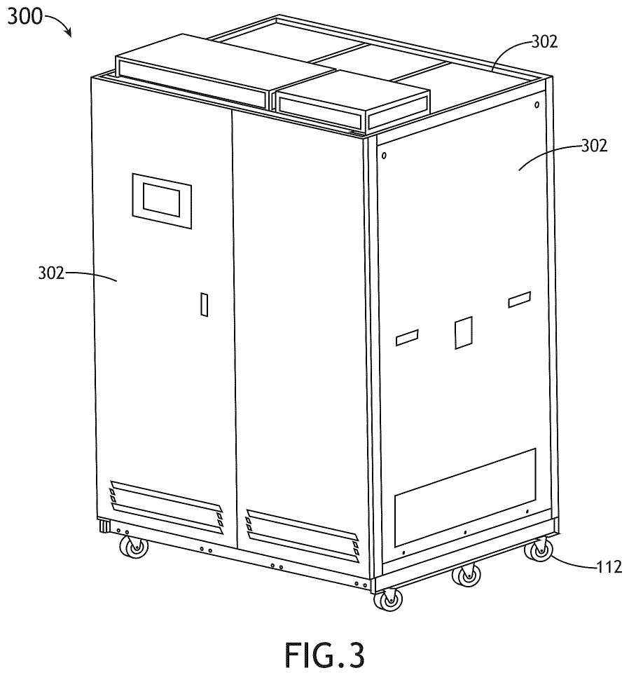

Referring to FIGS. 1A-3, a hybrid self-fixturing frame assembly 100 of the present disclosure is shown. In particular, FIG. 1A illustrates a simplified schematic of the hybrid self-fixturing assembly 100. In particular, FIG. 1B illustrates a simplified schematic of a base sub-assembly 102 of the hybrid self-fixturing assembly 100. In particular, FIG. 1C illustrates a simplified schematic of a side sub-assembly 104 of the hybrid self-fixturing assembly 100. FIG. 1D illustrates a simplified schematic of a top sub-assembly 106 of the hybrid self-fixturing assembly 100. In particular, FIGS. 2A-2C illustrate exploded views of the hybrid self-fixturing assembly 100. In particular, FIG. 3 illustrates a simplified schematic of an enclosure 300 including the hybrid self-fixturing assembly 100, in accordance with one or more embodiments of the present disclosure.

For purposes of the present disclosure, the term “hybrid self-fixturing frame assembly 100”, “self-fixturing frame assembly 100”, “frame assembly 100”, “assembly 100”, and variations thereof may be considered equivalent, unless otherwise noted herein.

The self-fixturing frame assembly 100 may include a hybrid of both welded and riveted components to produce the full frame assembly. For example, as shown in FIG. 1A, the self-fixturing frame assembly 100 may include, but is not limited to, a base sub-assembly 102, one or more side sub-assemblies 104, and a top assembly 106. For instance, as discussed further herein, one or more of the individual sub-assemblies (e.g., the base sub-assembly 102, the one or more side sub-assemblies 104, the top sub-assembly 106, or the like) may be self-fixtured via one or more fasteners (e.g., one or more rivets) and then welded. In this regard, the individual assemblies (e.g., the base sub-assembly 102, the one or more side sub-assemblies 104, the top sub-assembly 106, or the like) once constructed, may be coupled together to form the full frame assembly 100, as shown in FIG. 1A.

It is noted that the one or more fasteners may include any suitable fastener such as, but not limited to, one or more rivets, one or more bolts, one or more screws, and the like.

The base sub-assembly 102, the one or more side sub-assemblies 104, and the top assembly 106 may at least partially define a cavity 103 for installing IT infrastructure equipment such as, but not limited to, critical power infrastructure equipment (e.g., power distribution units (PDUs), universal power supplies (UPSs), static transfer switches (STSs), and the like), or the like.

Referring to FIG. 3, in some embodiments, the self-fixturing frame assembly 100 may be used to form an enclosure 300 (or cabinet 300) configured protect the IT infrastructure from the environment (e.g., debris, rodents, or the like). For example, the self-fixturing frame assembly 100 may couple to one or more panel walls 302. For instance, the one or more of the individual sub-assemblies (e.g., the base sub-assembly 102, the one or more side sub-assemblies 104, the top sub-assembly 106, or the like) may be configured to couple to the one or more panel walls 302. In a non-limiting example, as shown in FIG. 3, at least the side sub-assemblies 104 and the top assembly may couple to the one or more panel walls 302.

Where the cavity 103 of the enclosure 300 includes IT equipment, at least one of the one or more panel walls 302 may be configured to operate as a door or in some instances, may include a door. In this regard, the IT equipment within the enclosure 300 may be accessed by a user (e.g., for maintenance, installation, or the like).

Further, in some instances, one or more external components may thereafter be coupled to (or mounted on) the respective one or more panel walls 302, as shown in FIG. 3.

The one or more panel walls 302 may include one or more openings to allow for airflow or wire/cable management.

In some embodiments, the self-fixturing frame assembly 100 may be used to form an open enclosure. In this regard, wires/cables from the IT infrastructure within the cavity 103 may be routed between the respective self-fixturing frame assemblies 100 or other components on the IT infrastructure floor.

The self-fixturing frame assembly 100 (or one or more components of the self-fixturing frame assembly 100) may be formed of any suitable weldable material including, but not limited to, aluminum, steel, iron, copper, nickel, titanium, or the like.

It is noted herein that by fastening (e.g., riveting) together the individual components of the self-fixturing frame assembly 100, the frame assembly 100 may be considered self-fixturing, such that the components of the frame assembly 100 are fastened (e.g., riveted) together in the proper location and within the applicable tolerance specifications in preparation for the welding process. It is contemplated that the individual assemblies (e.g., the base sub-assembly 102, the one or more side sub-assemblies 104, the top sub-assembly 106, or the like) may be painted after they are assembled but prior to full frame assembly. In this regard, the paint booth dimensions may be reduced.

Referring to FIG. 1B, the base sub-assembly 102 may include a plurality of base frame members 108. For example, the base sub-assembly 102 may include a plurality of base frame members 108, where one or more of the plurality of base frame members 108 are coupled together via two or more fasteners (e.g., rivets, or the like). For instance, each base frame member of the plurality of base frame members 108 may include two or more through holes configured to receive the two or more rivets. In this regard, the respective base frame members of the plurality of base frame members 108 may be coupled together via the two or more rivets 110, such that the base sub-assembly 102 may be riveted together to self-fixture the individual components of the base sub-assembly 102 prior to welding. Referring to FIG. 2A, once the individual components of the base sub-assembly 102 are fixtured together via the rivets, the base sub-assembly 102 may be welded together at one or more welding locations 200.

In a non-limiting example, the plurality of base frame members 108 include a first base frame member 108a, a second base frame member 108b, a third base frame member 108c, and a fourth base frame member 108d that form an exterior perimeter of the base sub-assembly 102. Continuing with the above example, the plurality of base frame members 108 may further include a fifth base frame member 108e, a sixth base frame member 108f, and the seventh base frame member 108g coupled to one or more frame members of the exterior perimeter of the base sub-assembly 102. For instance, the first base frame member 108a may be coupled to the second base frame member 108b via a first set of two or more rivets 110a, the fourth base frame member 108d via a second set of two or more rivets 110b, and the fifth base frame member 108e via a third set of two or more rivets 110c. The second base frame member 108b may further be coupled to the third base frame member 108c via a fourth set of two or more rivets 110d, the sixth base frame member 108f via a fifth set of two or more rivets 110e, and the seventh base frame member 108g via a sixth set of two or more rivets 110f. The third base frame member 108c may further be coupled to the fourth base frame member 108d via a seventh set of two or more rivets 110g and the fifth base frame member 108e via an eighth set of two or more rivets 110h. The fifth base frame member 108e may be coupled to the sixth base frame member 108f via a ninth set of two or more rivets 110i and the seventh base frame member 108g via a tenth set of two or more rivets 110j.

Although FIGS. 1A-1B depict a specific base sub-assembly 102 configuration, it is noted herein that the base sub-assembly 102 may include any configuration of base frame members 108 (e.g., number, size, location, shape, or the like) and any configuration of fasteners (e.g., number, size, location, shape, type, or the like). It is further noted that the individual base frame members 108 may be fabricated using any fabrication process (e.g., cutting, folding, machining, punching, stamping, casting, or the like).

The base sub-assembly 102 may include one or more support members. For example, the base sub-assembly 102 may include one or more feet 112. In some instances, as shown in FIG. 2B, the base assembly 102 may include one or more static feet 112. In some instances, although not shown, the base sub-assembly 102 may include one or more adjustable feet 112 configured to adjust a height of the self-fixturing frame assembly 100. For instance, the base sub-assembly 102 may include one or more telescopic feet. By way of another example, as shown in FIG. 3, the base sub-assembly 102 may include one or more wheels 114.

Referring to FIG. 1C, each side sub-assembly 104 may include a plurality of side frame members 116 and one or more side panel members 118. For example, the side sub-assembly 104 may include a plurality of side frame members 116, where one or more of the plurality of side frame members 116 are coupled together via two or more fasteners (e.g., two or more rivets). For instance, each side frame member of the plurality of side frame members 116 may include two or more through holes configured to receive the two or more rivets. In this regard, the respective side frame members of the plurality of side frame members 116 may be coupled together via the two or more rivets and the one or more side panel members 118 may be coupled to the respective side frame members 118 via the two or more rivets, such that the side sub-assembly 104 may be riveted together to self-fixture the individual components of the side sub-assembly 104. Further, the side sub-assembly 104 may include one or more side panel members 118, where the one or more side panel members 118 are coupled to one or more respective side frame members 116 via the two or more rivets.

Once the individual components of each side sub-assembly 104 are fixtured together via the fasteners (e.g., rivets), each side sub-assembly 104 may be welded together at one or more welding locations. Referring to FIGS. 2B-2C, once each side sub-assembly 104 is welded together, each side sub-assembly 104 may be riveted to the base sub-assembly 102. For example, as shown in FIG. 2C, the side sub-assembly 104 may be mounted to a surface of the base sub-assembly 102 via one or more rivets 202. In this regard, the mounting between the side sub-assembly 104 and the base sub-assembly 102 may be considered flush (e.g., squared off).

In a non-limiting example, the plurality of side frame members 116 may include a first side frame member 116a, a second side frame member 116b, a third side frame member 116c, and a fourth side frame member 116d that form the exterior perimeter of the side sub-assembly 104. The first side frame member 116a may be coupled to the second side frame member 116b via a first set of two or more rivets 120a and the fourth side frame member 116d via a second set of two or more rivets 120b. The second side frame member 116b may be further coupled to the third side frame member 116c via a third set of two or more rivets 120c. The third side frame member 116c may be further coupled to the fourth side frame member 116d via a fourth set of two or more rivets 120d.

Although FIGS. 1A and 1C depict a specific side sub-assembly 104 configuration, it is noted herein that the side sub-assembly 104 may include any configuration of side frame members 116 (e.g., number, size, location, shape, or the like), any configuration of fasteners (e.g., number, size, location, shape, type, or the like), and/or any configuration of side panel members 118. It is further noted that the individual base frame members 108 may be fabricated using any fabrication process (e.g., cutting, folding, machining, punching, stamping, casting, or the like). In some cases, the side frame members 116 of the side sub-assembly 104 may be fabricated as a single piece, such that the respective side frame members 116 do not require fastening (e.g., riveting) or welding prior to coupling to the base sub-assembly 102.

Further, the side sub-assembly 104 may include one or more side panel members 118, where the one or more side panel members 118 are coupled to one or more respective side frame members 116 via the two or more rivets. In some embodiments, the one or more side panel members 118 may be further welded to the respective side frame members 116 after self-fixturing via the two or more rivets.

The one or more side panel members 118 may include one or more cut-outs 121 (or openings). In this regard, wires/cables may be routed through the one or more cut-outs 121. Further, equipment may be accessed via the one or more cut-outs 121.

The one or more side panel members 118 may further include one or more perforation holes 123. In this regard, the one or more perforation holes 123 may provide for greater air flow/circulation to the IT infrastructure within the cavity 103.

Referring to FIG. 1D, the top sub-assembly 106 includes one or more top frame members 122. For example, the top sub-assembly 106 may include a first top frame member 122a, a second top frame member 122b, and a third top frame member 122c.

The top frame members 122 may be structurally riveted to one or more side frame members 116 of each side sub-assembly 104 to establish a distance between the respective side sub-assemblies 104. For example, each top frame member 122a-c may be coupled to a first side sub-assembly 104 (e.g., the left side sub-assembly 104) and a second side sub-assembly 104 (e.g., right side sub-assembly 104). For instance, as shown in FIG. 1C, each side sub-assembly 104 may include one or more protrusions 124 configured to receive a portion of the one or more top frame members 122. In a non-limiting example, as shown in FIG. 1A, a first protrusion of the first side sub-assembly 104 (e.g., the left side sub-assembly 104) may receive a first end of the first top frame member 122a and a first protrusion of the second side sub-assembly 104 (e.g., the right side sub-assembly 104) may receive a second end of the first top frame member 122b. Continuing with the above example, a second protrusion of the first side sub-assembly 104 (e.g., the left side sub-assembly 104) may receive a first end of the third top frame member 122c and a second protrusion of the second side sub-assembly 104 (e.g., the right side sub-assembly 104) may receive a second end of the third top frame member 122c. In this regard, the respective protrusions 124 and the respective top frame members 122a, 122c may be coupled via the two or more rivets and two or more through holes. The second top frame member 122b may be riveted to the first side frame members 116a of each side sub-assembly 104. For example, a first end of the top frame member 122b may be riveted to the first side frame member 116a of the first side sub-assembly 104 (e.g., the left side sub-assembly 104) and the second end of the top frame member 122b may be riveted to the first side frame member 116a of the second side sub-assembly 104 (e.g., the right-side sub-assembly 104).

Although FIGS. 1A and 1D depicts a specific top sub-assembly 106 configuration, it is noted herein that the top sub-assembly 106 may include any configuration of top frame members 122 (e.g., number, size, location, shape, or the like), and/or any configuration of rivets (e.g., number, size, location, shape, or the like). It is further noted that the individual top frame members 122 may be fabricated using any fabrication process (e.g., cutting, folding, machining, punching, stamping, casting, or the like).

Once the side sub-assemblies 104 are riveted onto the base sub-assembly 102, the one or more top frame members 122 may be structurally riveted to the side-sub-assemblies 104 to form the full frame assembly 100.

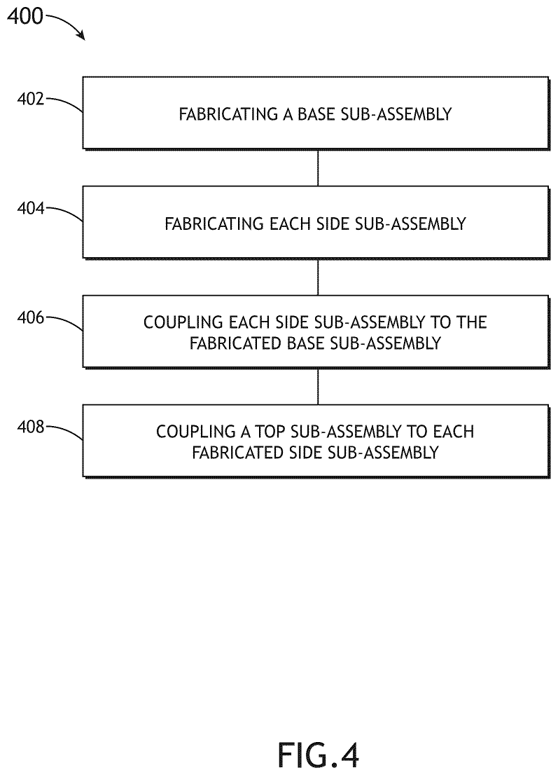

FIG. 4 is a flow chart depicting a method or process 400 for assembling the hybrid self-fixturing power product frame assembly 100, in accordance with one or more embodiments of the present disclosure. Applicant notes that the embodiments and enabling technologies described previously herein in the context of the self-fixturing frame assembly 100 and components thereof should be interpreted to extend to the method 400. It is further noted, however, that the method 400 is not limited to the architecture of the self-fixturing frame assembly 100.

In a step 402, the base sub-assembly may be fabricated. For example, the respective base frame members 108 may be fastened (e.g., riveted) together to self-fixture the base sub-assembly 102. Once self-fixtured, the respective base frame members 108 may be welded together.

In a step 404, each side sub-assembly may be fabricated. For example, the respective side frame members 116 may be fastened (e.g., riveted) together to self-fixture each side sub-assembly 104. Once self-fixtured, the respective side frame members 116 may be welded together.

In a step 406, each side sub-assembly may be coupled to the base sub-assembly. For example, the first side sub-assembly 104 may be coupled to a first side of the base sub-assembly 102 via a first set of rivets and the second sub-assembly 104 may be coupled to a second side of the base assembly 102 via a second set of fasteners (e.g., rivets).

In a step 408, the top sub-assembly may be coupled to each side sub-assembly. For example, the top frame members 122 of the top sub-assembly 106 may be coupled to each side sub-assembly 104 via one or more sets of fasteners (e.g., rivets).

It is contemplated that steps of the method 400 may be performed in any order, therefore, the above discussion should not be construed as limiting the scope of the present disclosure. For example, the side sub-assemblies 104 may be fabricated before the base sub-assembly 102. Further, the top sub-assembly may be coupled to the side sub-assemblies 104 prior to coupling the side sub-assemblies 104 to the base sub-assembly 102.

Once the top frame members 122 have been coupled to the side sub-assemblies 104 (which are coupled to the base sub-assembly 102), the full frame assembly 100 may be formed.

As previously discussed herein, the individual sub-assemblies (e.g., the base sub-assembly 102, the one or more side sub-assemblies 104, or the top sub-assembly 106) may be painted prior to assembly. For example, the base sub-assembly 102 may be painted before coupling the side sub-assembly 104 to the base sub-assembly 104. By way of another example, the one or more side sub-assemblies 104 may be painted prior to coupling to the base sub-assembly 102 and/or the top sub-assembly 106. By way of another example, the top frame members 122 of the top sub-assembly 106 may be painted prior to coupling to the side sub-assemblies 104.

Although FIG. 1A depicts only two side sub-assemblies 104, it is contemplated herein that the self-fixturing frame assembly 100 may include any number of side sub-assemblies 104 (e.g., one, two, three, four, or the like). Further, although FIG. 1A depicts the self-fixturing frame assembly 100 including a top sub-assembly 106, it is contemplated that the self-fixturing frame assembly 100 may not include a top sub-assembly 106.

In a general sense, those skilled in the art will recognize that the various aspects described herein which can be implemented, individually and/or collectively, by a wide range of hardware, software, firmware, or any combination thereof can be viewed as being composed of various types of “electrical circuitry.” Consequently, as used herein “electrical circuitry” includes, but is not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of random access memory), and/or electrical circuitry forming a communications device (e.g., a modem, communications switch, or optical-electrical equipment). Those having skill in the art will recognize that the subject matter described herein may be implemented in an analog or digital fashion or some combination thereof.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed:

1. A self-fixturing frame assembly comprising:
a base sub-assembly, the base sub-assembly including a plurality of base frame members, at least one base frame member of the plurality of base frame members coupled to an additional at least one base frame member of the plurality of base frame members via two or more fasteners, upon coupling the at least one base frame member to the additional at least one base frame member, the at least one base frame member being welded to the additional at least one base frame member;
one or more side sub-assemblies, each side sub-assembly of the one or more side sub-assemblies including a plurality of side frame members, at least one side frame member of the plurality of side frame members coupled to an additional at least one side frame member of the plurality of side frame members via the two or more fasteners, upon coupling the at least one side frame member to the additional at least one side frame member, the at least one side frame member being welded to the additional at least one side frame member, the one or more side sub-assemblies couplable to the base sub-assembly upon welding the at least one side frame member to the additional at least one side frame member; and
a top sub-assembly, the top sub-assembly including a plurality of top frame members, wherein the plurality of top frame members are configured to be coupled to the one or more side sub-assemblies.

2. The self-fixturing frame assembly of claim 1, wherein the two or more fasteners include two or more rivets.

3. The self-fixturing frame assembly of claim 1, wherein the plurality of top frame members includes three top frame members.

4. The self-fixturing frame assembly of claim 1, wherein the plurality of base frame members includes seven base frame members.

5. The self-fixturing frame assembly of claim 1, wherein the plurality of side frame members includes four side frame members.

6. The self-fixturing frame assembly of claim 1, wherein the base sub-assembly includes one or more feet.

7. The self-fixturing frame assembly of claim 1, wherein the base sub-assembly includes one or more wheels.

8. The self-fixturing frame assembly of claim 1, wherein each side sub-assembly further comprises:
one or more side panel members.

9. The self-fixturing frame assembly of claim 8, wherein one or more side panel members include one or more cut-outs.

10. The self-fixturing frame assembly of claim 8, wherein one or more side panel members include one or more perforations.

11. A method of fabricating a self-fixturing frame assembly comprising:
fabricating a base sub-assembly by coupling at least one base frame member of a plurality of base frame members coupled to an additional at least one base frame member of the plurality of base frame members via two or more fasteners, upon coupling the at least one base frame member to the additional at least one base frame member, the at least one base frame member being welded to the additional at least one base frame member;
fabricating one or more side sub-assemblies by coupling at least one side frame member of a plurality of side frame members coupled to an additional at least one side frame member of the plurality of side frame members via the two or more fasteners, upon coupling the at least one side frame member to the additional at least one side frame member, the at least one side frame member being welded to the additional at least one side frame member;
upon welding the at least one side frame member to the additional at least one side frame member, coupling the one or more side sub-assemblies to the base sub-assembly via the two or more fasteners; and
coupling a top sub-assembly to the one or more side sub-assemblies, the top sub-assembly including a plurality of top frame members, wherein the plurality of top frame members are configured to be coupled the one or more side sub-assemblies.

12. The method of claim 11, wherein the two or more fasteners include two or more rivets.

13. The method of claim 11, wherein the plurality of top frame members includes three top frame members.

14. The method of claim 11, wherein the plurality of base frame members includes seven base frame members.

15. The method of claim 11, wherein the plurality of side frame members includes four side frame members.

16. The method of claim 11, wherein the base sub-assembly includes one or more feet.

17. The method of claim 11, wherein each side sub-assembly further comprises:
one or more side panel members.

18. The method of claim 17, wherein one or more side panel members include one or more cut-outs.

19. The method of claim 17, wherein one or more side panel members include one or more perforations.

20. An enclosure comprising:
a self-fixturing frame assembly comprising:
a base sub-assembly, the base sub-assembly including a plurality of base frame members, at least one base frame member of the plurality of base frame members coupled to an additional at least one base frame member of the plurality of base frame members via two or more fasteners, upon coupling the at least one base frame member to the additional at least one base frame member, the at least one base frame member being welded to the additional at least one base frame member;
one or more side sub-assemblies, each side sub-assembly of the one or more side sub-assemblies including a plurality of side frame members, at least one side frame member of the plurality of side frame members coupled to an additional at least one side frame member of the plurality of side frame members via the two or more fasteners, upon coupling the at least one side frame member to the additional at least one side frame member, the at least one side frame member being welded to the additional at least one side frame member, the one or more side sub-assemblies couplable to the base sub-assembly upon welding the at least one side frame member to the additional at least one side frame member; and
a top sub-assembly, the top sub-assembly including a plurality of top frame members, wherein the plurality of top frame members are configured to be coupled to the one or more side sub-assemblies,
wherein the base sub-assembly, the one or more side sub-assemblies, and the top sub-assembly at least partially define a cavity configured to hold one or more pieces of equipment; and
one or more panel walls, wherein the one or more panel walls are configured to couple to at least one of the base sub-assembly, the one or more side sub-assemblies, or the top assembly.
